(19) United States
(12) Patent Application Publication
(10) Pub. No.: US 2017/0207365 A1
(43) Pub. Date: Jul. 20, 2017

(54) LAYERED ACTIVE REGION LIGHT EMITTING DIODE

(71) Applicant: Google Inc., Mountain View, CA (US)

(72) Inventors: Michael Grundmann, San Jose, CA (US); Martin F. Schubert, Mountain View, CA (US)

(21) Appl. No.: 15/001,951

(22) Filed: Jan. 20, 2016

(51) Int. Cl. H01L 33/14; H01L 33/00; H01L 33/42; H01L 33/06; H01L 33/32

(52) U.S. Cl. CPC H01L 33/145; H01L 33/06; H01L 33/32; H01L 33/42; H01L 33/007; H01L 33/0079

(57) ABSTRACT

An apparatus includes a p-type semiconductor material, an n-type semiconductor material, and an active region disposed between the p-type semiconductor material and the n-type semiconductor material. The active region emits light in response to a voltage applied across the active region, and the active region includes a quantum well region, a barrier region, and a capping region. The barrier region is disposed to confine charge carriers in the quantum well region. The capping region is disposed between the quantum well region and the barrier region, and the capping region is adjacent to the quantum well region to stabilize a material composition of the quantum well region. The quantum well region, the barrier region, and the capping region collectively form a first tri-layer structure.

### TECHNICAL FIELD

This disclosure relates generally to light emitting diodes, and in particular but not exclusively, relates to layered active region light emitting diodes.

### BACKGROUND INFORMATION

Light emitting diodes (LEDs) are semiconductor light emitters. In their simplest form, LEDs are a p-n junction that emits light when a voltage of sufficient magnitude is applied across the device. When the device is turned on, electrons combine with holes at the junction interface and release energy in the forms of light and heat. The color of the light (photon energy) is proportional to the size of the semiconductor bandgap and governed by the equation E=hv, where E is energy, h is Planck's constant, and v is the photon frequency.

Recently, LEDs have become ubiquitous and are used in a variety of applications including solid-state lighting, display technologies, and optical communications. The demands of lower power consumption and greater screen resolution have encouraged the miniaturization of these devices. State of the art screens may include many thousands of individual LED devices.

However, despite progress made in the diode field, there is still room for improvement. LED performance is tied to device dimensionality; meaning the size of the device may impact its performance and the materials used. At certain device dimensions some materials may exhibit superior performance due to unique electronic properties. However, at other dimensions these same unique electronic properties may cause a precipitous decrease in performance metrics.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified. The drawings are not necessarily to scale, emphasis instead being placed upon illustrating the principles being described.

FIG. 1A is a cross sectional illustration of one embodiment of a light emitting diode (LED), in accordance with an embodiment of the disclosure.

FIG. 1B is a cross sectional illustration of one embodiment of a light emitting diode (LED), in accordance with an embodiment of the disclosure.

FIG. 2 is a functional block diagram illustrating a micro-LED display system, in accordance with an embodiment of the disclosure.

FIG. 3 is a flow chart describing a method of fabricating an LED, in accordance with several embodiments of the disclosure.

FIGS. 4A-4E illustrate a method of fabricating an LED, in accordance with an embodiment of the disclosure.

### DETAILED DESCRIPTION

Embodiments of an apparatus and method of fabrication for a layered active region light emitting diode are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

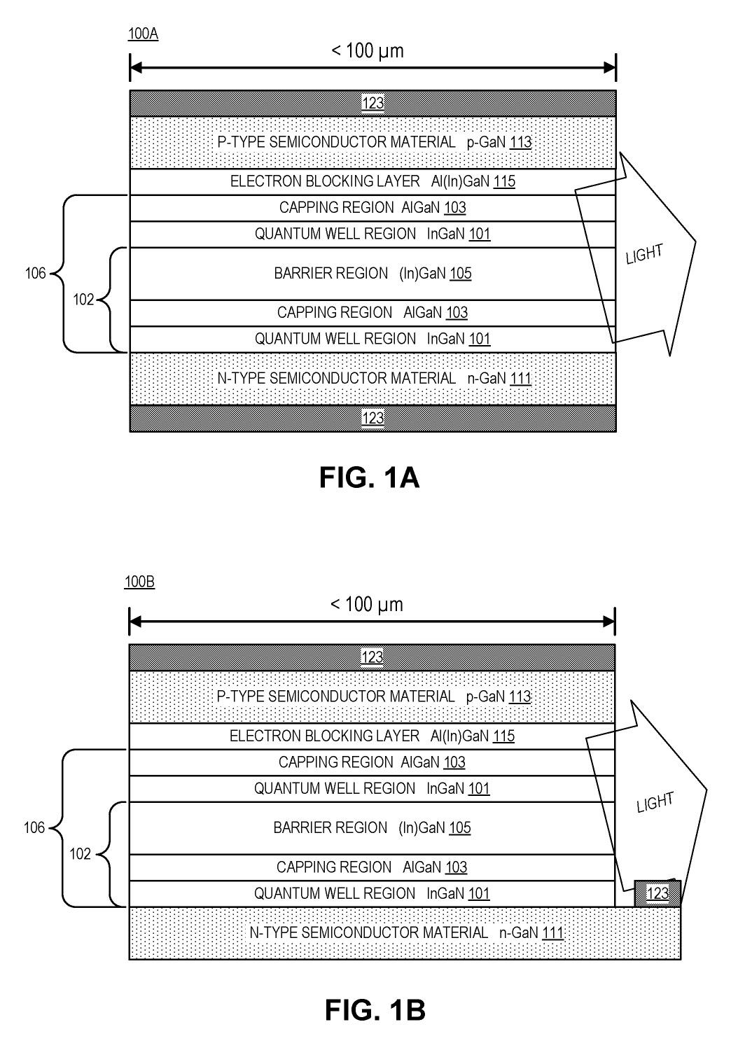

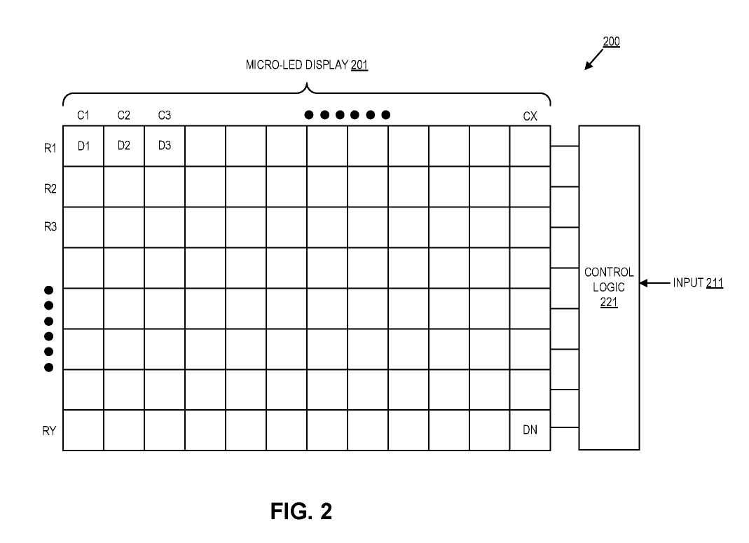

FIG. 1A is a cross sectional illustration of one embodiment of light emitting diode (LED) 100A, in accordance with an embodiment of the disclosure. LED 100A includes: n-type semiconductor material 111, active region 106 (including tri-layer structure 102), p-type semiconductor material 113, electron blocking layer 115 and electrodes 123. Active region 106 (and tri-layer structure 102) include quantum well region 101, capping region 103, and barrier region 105. In one or more embodiments, LED 100A (or part of LED 100A) may be part of a larger apparatus.

Active region 106 is disposed between p-type semiconductor material 113 and n-type semiconductor material 111. In one embodiment, p-type semiconductor material 113 and n-type semiconductor material 111 include GaN. Active region 106 emits light in response to a voltage applied across active region 106, and active region 106 includes quantum well region 101, capping region 103, and barrier region 105. Barrier region 105 is disposed to confine charge carriers in quantum well region 101. Capping region 103 is disposed between quantum well region 101 and barrier region 105, and capping region 103 is adjacent to quantum well region 101 to stabilize a material composition of quantum well region 101. Collectively, quantum well region 101, barrier region 105, and capping region 103 form a first tri-layer structure 102. In one embodiment, quantum well region 101 includes InGaN, capping region 103 includes AlGaN, and barrier region 105 includes (In)GaN.

In one embodiment, active region 106 includes a plurality of quantum well regions 101, a plurality of barrier regions 105, and a plurality of capping regions 103. This may mean that active region 106 includes a plurality of tri-layer structures 102, where barrier region 105 (of first tri-layer structure 102) contacts a quantum well region 101 of a second tri-layer structure 102. In the depicted embodiment, only one full tri-layer structure 102 is present with an additional quantum well region 101 and an additional capping region 103. In one embodiment, there may be between 1 and 10 tri-layer structures 102 in active region 106. Furthermore, any number of additional layers (such as quantum well region 101, capping region 103, and barrier region 105) may be present in LED 100A and not be part of a tri-layer structure 102. In the depicted embodiment, LED 100A also includes electron blocking layer 115 disposed between p-type semiconductor material 113 and active region 106 to enhance the quantum efficiency of the device. However, in one embodiment, a spacer may be present between active region 106 and electron blocking layer 115.

As shown, first electrode 123 may be coupled to p-type semiconductor material 113, and second electrode 123 may be coupled to the n-type semiconductor material 111. In one embodiment, at least one of the first electrode 123 and second electrode 123 is transparent. As illustrated, the p-type semiconductor material 113, n-type semiconductor material 111, and active region 106 are disposed between first electrode 123 and second electrode 123.

FIG. 1B is a cross sectional illustration of one embodiment of a light emitting diode (LED) 100B, in accordance with an embodiment of the disclosure. The LED 100B depicted in FIG. 1B, is similar to the LED 100A depicted in FIG. 1A; however, one major distinction is the configuration of electrodes 123. In the depicted embodiment, the lateral bounds of n-type semiconductor material 111 extend beyond the lateral bounds of active region 106 and the lateral bounds of p-type semiconductor material 113. One of electrodes 123 is disposed on the lateral region of n-type semiconductor material 111 that extends beyond the lateral bounds of active region 106. However, in a different embodiment, the lateral bounds of p-type semiconductor material 113 may extend beyond the lateral bounds of active region 106 and the lateral bounds of n-type semiconductor material 111. In the same embodiment, one of electrodes 123 is disposed on the lateral region of p-type semiconductor material 113 that extends beyond the lateral bounds of active region 106. In the depicted embodiment, a lateral dimension of the active region 106 (and/or the lateral dimension of the device) is less than 100 μm. In another or the same embodiment, the active region 106 (and/or the lateral dimension of the device) is ≦50 μm. In other embodiments, the lateral dimension may be even smaller such as ≦5 μm, ≦10 μm, ≦20 μm, ≦30 μm, ≦40 μm, or the like. In one embodiment, the width of LED 100B may be as small as 1×1 μm, 2×2 μm, 3×10 μm, or 10×10 μm. Further, the top-down profile of LED 100B may be square, rectangular, triangular, hexagonal, or rounded (circle or oval), or the like.

In one embodiment, InGaN is used in quantum well region 101 of LED 100B, and LED 100B emits red light. In general, InGaN may be considered a sub-optimal material for the quantum well region of a layered red LED due to—among other things—its low quantum efficiency and short charge carrier diffusion length (relative to conventional red emitters like AlInGaP, which may have a diffusion length an order of magnitude longer than InGaN). Accordingly, at typical device dimensions (e.g., >100 μm active region diameter), a red InGaN based LED may be highly inefficient compared to an AlInGaP based LED. However, in a micro-scale device based on AlInGaP, charge carriers have a high probability of traveling to the edge of the device (due to the long diffusion length of AlInGaP) and being consumed by surface charge trapping states with short lifetimes. This results in an inefficient LED. As an alternative, InGaN's short diffusion length, and longer surface state lifetime, may make it a better choice for microscale devices. Thus in some micro-scale applications, the use of InGaN in a quantum well region 101 may enhance device performance compared to AlInGaP as a result of InGaNs short carrier diffusion length and longer surface state lifetime. Furthermore, the low efficiency of red InGaN LEDs may be due to low InGaN crystal quality. Capping region 103 in the instant disclosure allows for higher temperature processing to anneal out defects and improve crystal quality. As a result, red InGaN devices (with the disclosed structure) may outperform red AlInGaP devices.

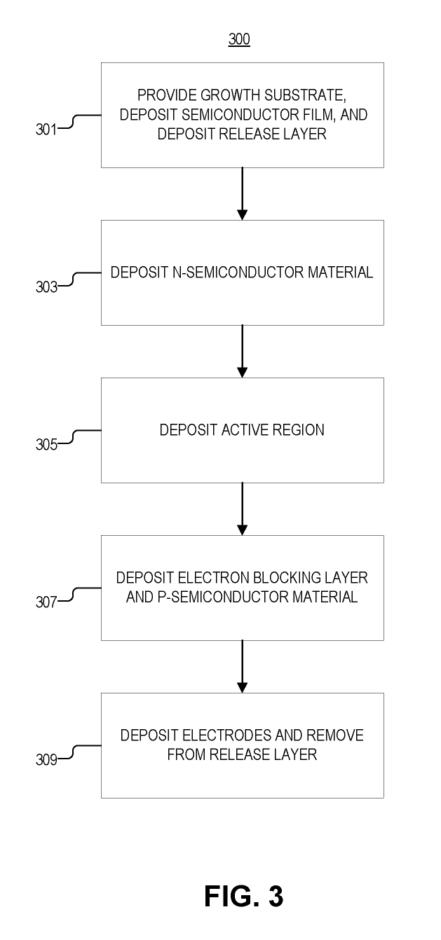

FIG. 2 is a functional block diagram illustrating an apparatus including micro-LED display system 200, in accordance with an embodiment of the disclosure. Micro-LED display system 200 includes: micro-LED display 201, control logic 221, and input 211. In one embodiment, micro-LED display 201 is a two-dimensional array including a plurality of LEDs (e.g., D1, D2 . . . , DN) where on or more of LEDs (D1, D2 . . . , DN) may include the LED of FIG. 1A or 1B (e.g., LED 100A). In one embodiment, the active region (e.g., active region 106) of the LED depicted in FIG. 1A is included in a first light emitting diode in the plurality of LEDs, and the plurality of LEDs are arranged into an array and communicatively coupled to a display module (i.e., circuitry backing micro-LED display 201). As illustrated, diodes are arranged into rows (e.g., rows R1-RY) and columns (e.g., columns C1-CX) to project image light and form an image on micro-led display 201. However, it should be noted that the rows and columns do not necessarily have to be linear and may take other shapes depending on use case. The LEDs in micro-LED display 201 may be color LEDs arranged into pattern where sub-groups of LED's (corresponding to single image pixels) include red, green, and blue LEDs. The red, green, and blue LEDs in the sub-sub group may be activated at different times and with different intensities such that the viewer sees colors other than red, green, and blue. Alternatively, the LEDs in micro-LED display system 200 may be white LEDs disposed behind a color filter array where sub-groups of LED's are disposed behind a group of red, green, and blue color filters. In another embodiment, UV or blue LEDs may be used in conjunction with a color conversion layer (such as a phosphor or quantum dot layer) to achieve red, green, and blue light emission. LEDs in the sub-group may be activated at different times and intensities such that the viewer sees colors other than the red, green, and blue provided by the color filters. Further, micro-LED display system 200 may display a static image or may display an active image depending on the data received from control logic 221. In one embodiment, the active region thickness of a single diode can range in size from nanometer to micron scale, but more specifically 3-100 nm.

In one embodiment, micro-led display 201 is controlled by control logic 221 coupled to the display module. Control logic 221 may include a processor (or microcontroller), switching power supply, etc. The processor or microcontroller may control individual LEDs in micro-led display 201, or control groups of mico-LEDs.

In the depicted embodiment, micro-led display system 200 includes input 211. Input 211 may include user input via buttons, USB port, wireless transmitter, HDMI port, video player, etc. Input 211 may also include software installed on control logic 221 or data received from the internet or other source.

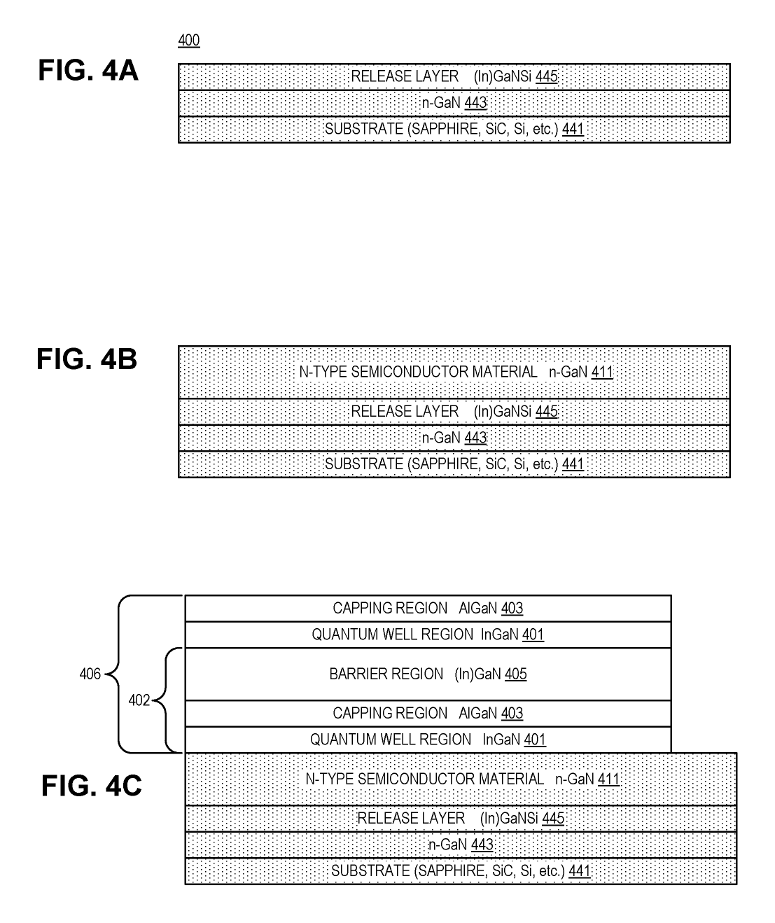

FIG. 3 is a flow chart describing a process 300 of fabricating an LED (e.g., LED 100A or LED 100B), in accordance with several embodiments of the disclosure. The order in which some or all of process blocks 301-309 appear in process 300 should not be deemed limiting. Rather, one of ordinary skill in the art having the benefit of the present disclosure will understand that some of the process 300 may be executed in a variety of orders not illustrated, or even in parallel. Further, FIG. 3 depicts only part of the LED fabrication process and may omit steps in order to prevent obscuring certain aspects.

Process block 301 illustrates providing a substrate. In one embodiment, the substrate may include sapphire, silicon carbide, silicon, or otherwise. A semiconductor layer is deposited on the substrate, and a release layer is deposited on top of the semiconductor layer. In one embodiment, the release layer is InGaN:Si. However, in alternate embodiments, the release layer may include InGaN super lattices or quasi-bulk layers to enable photo-electrochemical induced etching, or may be heavily doped with an n-type dopant element such as Si to enable electrochemical etching.

Process block 303 shows forming a first semiconductor material. In one embodiment, the first semiconductor layer is disposed on the release layer and includes GaN. However, other semiconductor materials may be used depending on the desired device architecture.

Process block 305 illustrates depositing the active region (e.g., active region 106). The active region includes a quantum well region, a barrier region, and a capping region. Together these three layers form a tri layer structure which may be repeated many times to form a multilayer LED.

Process block 307 depicts depositing an electron blocking layer and a p-type semiconductor material. The electron blocking layer may increase device efficiency by preventing electrons from flowing into the p-type semiconductor region resulting in non-radiative charge-recombination based losses.

Process block 309 shows depositing electrodes and removing the LED device from the release layer. In one embodiment, removing the LED device from the release layer may occur before or after deposing electrodes. In one embodiment (e.g., LED 100B of FIG. 1B), electrodes may be deposited prior to removal of the LED from the substrate or after removal of the LED from the substrate. However, in another embodiment (e.g., LED 100A of FIG. 1A), the LED device needs to be removed from the substrate prior to depositing electrodes, since the electrodes are disposed on opposite sides of the LED device.

Although not depicted, after each LED device is separated from the substrate they may be transferred to a display panel and connected to control circuitry to form an array.

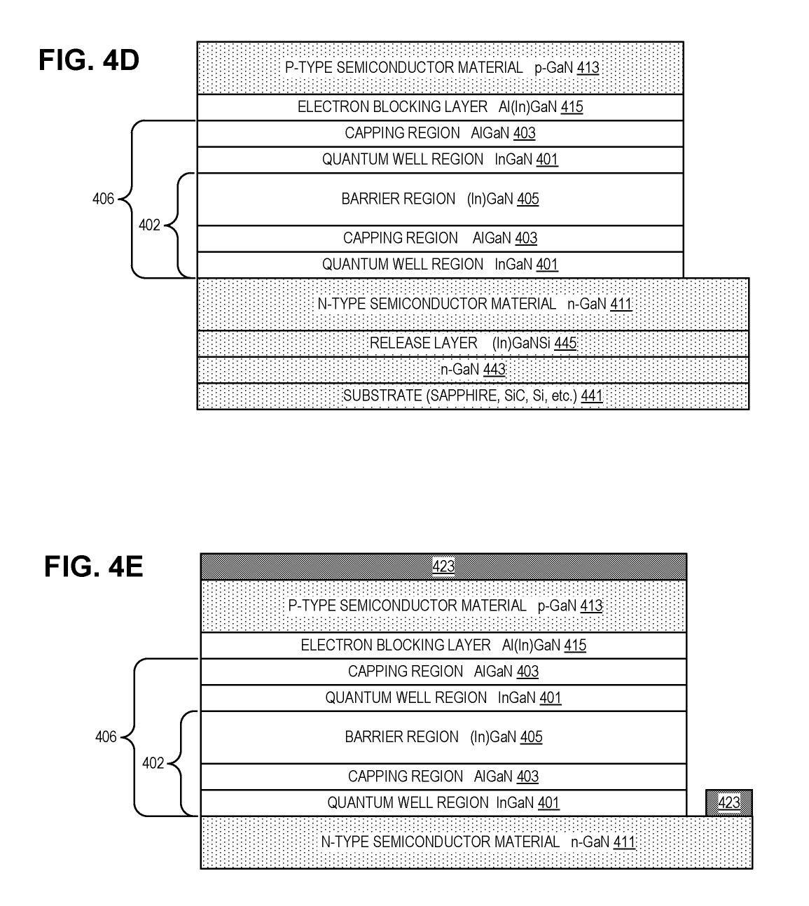

FIGS. 4A-4E illustrate a method 400 of fabricating an LED (e.g., LED 100B), in accordance with an embodiment of the disclosure. The order in which some or all of FIGS. 4A-4E appear in method 400 should not be deemed limiting. Rather, one of ordinary skill in the art having the benefit of the present disclosure will understand that some of the method 400 may be executed in a variety of orders not illustrated, or even in parallel.

FIG. 4A shows providing substrate 441 for growth of an LED (e.g., LED 100B). In the depicted embodiment, substrate 441 may include sapphire, silicon carbide, silicon, or the like. An n-type semiconductor (e.g., n-type GaN 443) is grown on the surface of substrate 441. Release layer 445 is then grown on the surface of the semiconductor layer 443. Semiconductor layer 443 is disposed between substrate 441 and release layer 445. In one embodiment, release layer 445 includes InGaN:Si.

FIG. 4B depicts forming first semiconductor material 411 (with a first majority charge carrier type) on a first side of release layer 445. A second side of release layer 445 is disposed over the substrate 441.

FIG. 4C depicts depositing active region 406 on first semiconductor material 411. Active region 406 includes quantum well region 401, barrier region 405, and capping region 403. In one embodiment, quantum well region 401 has a high indium content of InN≧20%. In one embodiment, quantum well region 401 is disposed between barrier region 405 and capping region 403. Together, quantum well region 401, barrier region 405, and capping region 403 form first tri-layer structure 402. In one embodiment, depositing active region 406 includes forming a plurality of quantum well regions 401, a plurality of barrier regions 405, and a plurality of capping regions 403. In another or the same embodiment, depositing active region 406 includes forming a plurality of tri-layer structures 402, where barrier region 405 of the first tri-layer structure 402 contacts quantum well region 401 of second tri-layer structure 402.

In operation, capping region 403 may improve material quality of subsequently deposited barrier regions 405 by allowing barrier region 405 to be grown at a high temperature and improve the starting morphology of barrier region 405. For example, in embodiments where capping region 403 includes AlGaN or Al(InGa)N and barrier region 405 includes InGaN, the AlGaN may be grown smoother than InGaN, providing an optimal growth layer for a subsequent InGaN deposition. Furthermore, in some instances, quantum wells 401 with high indium content may thermally decompose in subsequent high-temperature deposition processes. Decomposition may result in N-vacancy formation or other extended and point defects in quantum well 401. Capping region 403 may help mitigate the effects of decomposition due to thermal cycling. Barrier regions 405 may have a larger bandgap than quantum well regions 401, and help confine charge carriers to their respective quantum well 401. Multiple tri-layer structures 102 may be used to yield a larger overall active region 106 volume, and may lower charge carrier density at a given current density level. Accordingly, high-carrier-density losses (such as Auger recombination) are reduced. In one embodiment, the quantum well region 401 may be 0.5-3 nm thick, capping region 403 may be 0.5-2 nm thick, and barrier region 405 may be 0.5-20 nm thick. In another or the same embodiment, quantum well region 401 may be 1-6 times as thick as capping region 403, and barrier region may be 1-40 times as thick as capping region 103.

FIG. 4D shows depositing second semiconductor material 413 of a second majority charge carrier type (opposite the first majority charge carrier type). The active region 406 is disposed between first semiconductor material 411 and second semiconductor material 413. The depicted embodiment also shows forming electron blocking layer 415, where electron blocking layer 415 is disposed between active region 406 and second semiconductor material 413. Electron blocking layer 415 may include Al(In)GaN. In one embodiment, forming first semiconductor material 411 and second semiconductor material 413 includes depositing GaN.

FIG. 4E illustrates removing release layer 445 to release first semiconductor material 411, second semiconductor material 413, and active region 406 from substrate 441. This may be achieved through photochemical and/or electrochemical etching. FIG. 4D also depicts forming first electrode 423 and second electrode 423. As shown, first electrode 423 is coupled to first semiconductor material 411 and second electrode 423 is coupled to second semiconductor material 413.

It should be noted that for all deposition and formation processes, any suitable material deposition technique may be employed to form the desired structure. For instance, to form active region 406, atomic layer deposition, chemical vapor deposition, molecular beam epitaxy, thermal evaporation, or the like, may all be used to form any of the individual layers of device architecture. Furthermore, any appropriate process gas or precursor material may be used to form the individual semiconductor/metal layers. For instance, when forming a layer/region including Ga, either GaH₄ or GaCl₄ may be used to grow the layer. In process where templating of layers is involved, either a positive or negative photoresist may be employed. Although this disclosure sets out several different material compositions that may be used in making the LED devices, in other embodiments (not discussed to avoid obscuring certain aspects) other semiconductor elements/compounds may be employed. For example, semiconductor material layers/regions may include a single group four element (e.g., C, Si, Ge, Sn, etc.), or my include a compound with group 3 elements (B, Al, Ga, In, etc), group four elements, group 5 elements (N, P, As, Sb etc.) or any other suitable composition. Example compounds include: AlGaInP, AlGaN, AlGaInN, Al(GaIn)AsP, AlAs, GaAs, GaAsP, GaP, GaN, GaAlAs, InGaN, SiC, or the like. Additionally, semiconductor material or other pieces of device architecture may be coated with phosphor to create phosphor-based or phosphor-converted LEDs.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. An apparatus, comprising:
a p-type semiconductor material;
an n-type semiconductor material; and
an active region disposed between the p-type semiconductor material and the n-type semiconductor material, wherein the active region emits light in response to a voltage applied across the active region, and wherein the active region includes:
a quantum well region;
a barrier region disposed to confine charge carriers in the quantum well region; and
a capping region disposed between the quantum well region and the barrier region, wherein the capping region is adjacent to the quantum well region to stabilize a material composition of the quantum well region, and wherein the quantum well region, the barrier region, and the capping region collectively form a first tri-layer structure.

2. The apparatus of claim 1, wherein the quantum well region includes InGaN, the capping region includes AlGaN, and the barrier region includes (AlIn)GaN.

3. The apparatus of claim 1, wherein the active region includes a plurality of quantum well regions, a plurality of barrier regions, and a plurality of capping regions.

4. The apparatus of claim 3, further comprising a plurality of tri-layer structures, wherein the barrier region of the first tri-layer structure contacts a quantum well region of a second tri-layer structure.

5. The apparatus of claim 1, wherein a lateral diameter of the active region is less than 100 μm.

6. The apparatus of claim 1, wherein the p-type semiconductor material includes GaN and the n-type semiconductor material includes GaN.

7. The apparatus of claim 1, further comprising an electron blocking layer disposed between the active region and the p-type semiconductor material.

8. The apparatus of claim 1, wherein the active region is included in a first light emitting diode (LED) in a plurality of LEDs, and wherein the plurality of LEDs are arranged into an array and communicatively coupled to a display module.

9. The apparatus of claim 8, wherein the display module is coupled to control logic to control operation of the plurality of LEDs.

10. The apparatus of claim 1, further comprising a first electrode and a second electrode, wherein the first electrode is coupled to the p-type semiconductor material and the second electrode is coupled to the n-type semiconductor material, and wherein at least one of the first electrode and second electrode is transparent.

11. The apparatus of claim 10, wherein the p-type semiconductor material, the n-type semiconductor material, and active layer are disposed between the first electrode and the second electrode.

12. A method of fabricating a light emitting diode (LED), comprising:
forming a first semiconductor material of a first majority charge carrier type on a first side of a release layer, wherein a second side of the release layer is disposed over a substrate;
depositing an active region on the first semiconductor material, wherein the active region includes:
a quantum well region, a barrier region, and a capping region, wherein the quantum well region, the barrier region, and the capping region form a first tri-layer structure; and
depositing a second semiconductor material of a second majority charge carrier type, wherein the second majority charge carrier type is opposite the first majority charge carrier type, and wherein the active region is disposed between the first semiconductor material and the second semiconductor material; and
removing the release layer to release the first semiconductor material, the second semiconductor material, and the active region from the substrate.

13. The method of claim 12, wherein the quantum well region includes InGaN, the capping region includes AlGaN, the barrier region includes (In)GaN, and the release layer includes InGaN:Si.

14. The method of claim 12, wherein depositing the active region includes forming plurality of quantum well regions, a plurality of barrier regions, and a plurality of capping regions.

15. The method of claim 14, wherein depositing the active region includes forming a plurality of tri-layer structures, wherein the barrier region of the first tri-layer structure contacts the quantum well region of a second tri-layer structure, and wherein the quantum well region is disposed between the barrier region and the capping region.

16. The method of claim 12, further comprising forming a semiconductor layer between the substrate and the release layer.

17. The method of claim 12, further comprising forming an electron blocking layer disposed between the active region and the second semiconductor material.

18. The method of claim 17, wherein the electron blocking layer includes Al(In)GaN.

19. The method of claim 12, wherein forming the first semiconductor material and the second semiconductor material includes depositing GaN.

20. The method of claim 12, further comprising forming a first electrode and a second electrode, wherein the first electrode is coupled to the first semiconductor material and the second electrode is coupled to the second semiconductor material.
